(19) United States
(12) Patent Application Publication
(10) Pub. No.: US 2025/0252907 A1
(43) Pub. Date: Aug. 7, 2025

(54) DISPLAY DEVICE

(71) Applicant: Innolux Corporation, Miaoli County (TW)

(72) Inventors: Shu-Hui Chang, Miaoli County (TW); Chih-Lung Lin, Miaoli County (TW); Chia-Hao Tsai, Miaoli County (TW); Yung-Hsun Wu, Miaoli County (TW)

(73) Assignee: Innolux Corporation, Miaoli County (TW)

(21) Appl. No.: 19/030,748

(22) Filed: Jan. 17, 2025

Related U.S. Application Data
(60) Provisional application No. 63/550,603, filed on Feb. 7, 2024.

(30) Foreign Application Priority Data
Nov. 19, 2024 (CN) 202411657119.6

(51) Int. Cl. G09G 3/32; H10H 29/34

(52) U.S. Cl. CPC G09G 3/32; H10H 29/345; G09G 2320/0242; G09G 2320/0666; G09G 2320/0686; G09G 2330/023

(57) ABSTRACT

A display device includes first and second light-emitting units. An external quantum efficiency of the first light-emitting unit at a first current is less than at a second current. An external quantum efficiency of the second light-emitting unit at the first current is greater than at the second current. The first and second light-emitting units are operated at first and second operating currents respectively. When the first operating current is less than or equal to a threshold current, a quantity of the first light-emitting unit is greater than a quantity of the second light-emitting unit; and when the first operating current is greater than the threshold current, the quantity of the first light-emitting unit is less than the quantity of the second light-emitting unit. The first current is less than the second current. The threshold current is greater than the first current and less than the second current.

### CROSS-REFERENCE TO RELATED APPLICATION

This application claims the priority benefit of U.S. provisional application Ser. No. 63/550,603, filed on Feb. 7, 2024 and China application serial no. 202411657119.6, filed on Nov. 19, 2024. The entirety of each of the above-mentioned patent applications is hereby incorporated by reference herein and made a part of this specification.

### BACKGROUND

### Technical Field

The disclosure relates to a display device, and in particular, to a display device that may achieve the requirements of high luminous efficiency or high brightness for each color in a pixel unit.

### Description of Related Art

Electronic devices or tiled electronic devices have been widely used in different fields such as communication, display, automotive, or aviation. With the rapid development of electronic devices, electronic devices are being developed to be thinner and lighter. Therefore, the requirements for reliability or quality of electronic devices are getting higher.

### SUMMARY

The disclosure provides a display device allowing each color in a pixel unit to meet the requirements of high luminous efficiency or high brightness, or the pixel unit may simultaneously meet the color point requirements of the display device and have low power consumption.

According to an embodiment of the disclosure, a display device includes at least one first light-emitting unit and at least one second light-emitting unit. An external quantum efficiency of the first light-emitting unit at a first current is less than an external quantum efficiency thereof at a second current, and the first light-emitting unit is operated at a first operating current. An external quantum efficiency of the second light-emitting unit at the first current is greater than an external quantum efficiency thereof at the second current, and the second light-emitting unit is operated at a second operating current. When the first operating current is less than or equal to a threshold current, a quantity of the first light-emitting unit is greater than a quantity of the second light-emitting unit; and when the first operating current is greater than the threshold current, the quantity of the first light-emitting unit is less than the quantity of the second light-emitting unit. The first current is less than the second current, and the threshold current is greater than the first current and less than the second current.

According to an embodiment of the disclosure, a display device includes at least one first light-emitting unit and at least one second light-emitting unit. The first light-emitting unit has a first light-emitting area, an external quantum efficiency of the first light-emitting unit at a first current is less than an external quantum efficiency thereof at a second current, and the first light-emitting unit is operated at a first operating current. The second light-emitting unit has a second light-emitting area, and an external quantum efficiency of the second light-emitting unit at the first current is greater than an external quantum efficiency thereof at the second current. When the first operating current is less than or equal to a threshold current, the first light-emitting area is greater than the second light-emitting area; and when the first operating current is greater than the threshold current, the first light-emitting area is less than the second light-emitting area. The first current is less than the second current, and the threshold current is greater than the first current and less than the second current.

According to an embodiment of the disclosure, a display device includes at least one first light-emitting unit, a first light enhancing unit, at least one second light-emitting unit, and a second light enhancing unit. An external quantum efficiency of the first light-emitting unit at a first current is less than an external quantum efficiency thereof at a second current, and the first light-emitting unit is operated at a first operating current. The first light enhancing unit is disposed on the first light-emitting unit and has a first area. An external quantum efficiency of the second light-emitting unit at the first current is greater than an external quantum efficiency thereof at the second current. The second light enhancing unit is disposed on the second light-emitting unit and has a second area. When the first operating current is less than or equal to a threshold current, the first area is greater than the second area; and when the first operating current is greater than the threshold current, the first area is less than the second area. The first current is less than the second current, and the threshold current is greater than the first current and less than the second current.

### BRIEF DESCRIPTION OF THE DRAWINGS

The accompanying drawings are included to further understand the disclosure, and the drawings are incorporated in the specification and constitute a part of the specification. The drawings illustrate embodiments of the disclosure and, together with the description, serve to explain principles of the disclosure.

FIG. 1A is a partial top view of the display device of the first embodiment of the disclosure.

FIG. 1B is a graph showing the relationship between external quantum efficiency and current of the light-emitting unit in the display device of FIG. 1A.

FIG. 2 is a partial top view of the display device of the second embodiment of the disclosure.

FIG. 3 is a partial top view of the display device of the third embodiment of the disclosure.

FIG. 4 is a partial top view of the display device of the fourth embodiment of the disclosure.

FIG. 5 is a partial top view of the display device of the fifth embodiment of the disclosure.

FIG. 6A is a partial top view of the display device of the sixth embodiment of the disclosure.

FIG. 6B is a graph showing the relationship between external quantum efficiency and current of the light-emitting unit in the display device of FIG. 6A.

FIG. 7 is a partial top view of the display device of the seventh embodiment of the disclosure.

FIG. 8 is a partial top view of the display device of the eighth embodiment of the disclosure.

FIG. 9 is a partial top view of the display device of the ninth embodiment of the disclosure.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the multiple drawings in the disclosure depict a part of the electronic device, and certain elements in the drawings are not drawn to actual scale. In addition, the quantity and dimension of each element in the figures are for illustration, and are not intended to limit the scope of the disclosure.

In the following specification and claims, words such as “containing” and “including” are open-ended words, so they should be interpreted as meaning “containing but not limited to . . .”

It should be understood that, when an element or film is referred to as being “on” or “connected to” another element or film, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third” . . . may be used to describe various constituent elements, the constituent elements are not limited to these terms. This term is used to distinguish a single constituent element from other constituent elements in the specification. The same terms may be not used in the claims, but are replaced by first, second, third . . . in the order in which elements are declared in the claims. Therefore, in the following specification, a first constituent element may be a second constituent element in the claims.

In this article, the terms “about”, “approximately”, “substantially”, “essentially” usually mean within 10%, or within 5%, or within 3%, or within 2%, or within 1%, or within 0.5% of a given value or range. The quantities given here are approximate quantities, that is, without specific instructions such as “about”, “approximately”, “substantially”, “essentially”, the meanings of “about”, “approximately”, “substantially”, “essentially” may still be implied.

In some embodiments of the disclosure, terms related to joining, connecting, such as “connecting”, “interconnecting”, etc., unless otherwise specified, may mean that two structures are in direct contact, or it may also mean that the two structures are not in direct contact, and there are other structures disposed between the two structures. Moreover, the terms of bonding and connecting may also include the case where both structures are movable or both structures are fixed. In addition, the term “coupling” includes any direct and indirect electrical connection means.

In some embodiments of the disclosure, an optical microscope (OM), a scanning electron microscope (SEM), a film thickness profiler (α-step), an ellipsometer, or other suitable methods may be used to measure the area, width, thickness, or height of each element, or the distance or spacing between the elements. Specifically, according to some embodiments, an SEM may be used to obtain a cross-sectional structure image including the elements to be measured, and measure the area, width, thickness, or height of each element, or the distance or spacing between the elements.

An electronic device of the disclosure may include a display device, an antenna device, a sensing device, a vehicle device, or a tiling device, but the disclosure is not limited thereto. The electronic device may be a bendable or flexible electronic device. The display device may be any type of display device, such as a color display device, a transparent display device, a double-sided display device, a virtual reality display device, an augmented reality display device, a 3D display device, a tiling display device, a flexible display device, a folding display device, a stretchable display device, a rollable display device, but the disclosure is not limited thereto. In some embodiments, the display device may include a self-luminous display device or a non-self-luminous display device. The non-self-luminous display device may include a liquid-crystal display device, but the disclosure is not limited thereto. The self-luminous display device may include a light-emitting diode, a light conversion layer, or other suitable materials, or a combination thereof, but the disclosure is not limited thereto. The light-emitting diode may include, for example, an organic light-emitting diode (OLED), a mini LED, a micro LED, a quantum dot (QD) LED (for example, QLED or QDLED), fluorescence, phosphor, or other suitable materials, and the materials may be arranged and combined in any way, but the disclosure is not limited thereto. The antenna device may be, for example, a device having communication and/or modulation electromagnetic wave functions, such as a liquid-crystal antenna, a wireless router (WiFi router), a reconfigurable intelligent surface device, or a suitable combination of the above, but the disclosure is not limited thereto. The tiling device may be, for example, a display tiling device or an antenna tiling device, but the disclosure is not limited thereto. The shape of the electronic device may be, for example, a rectangle, a circle, a polygon, a shape having curved edges, a curved surface, or other suitable shapes. The electronic device may have a peripheral system such as a drive system, a control system, a light source system, a shelf system, etc. The electronic device may include an electronic unit, wherein the electronic unit may include a passive element and an active element, such as a capacitor, a resistor, an inductor, a diode, a transistor, a sensor, etc. It should be noted that the electronic device of the disclosure may be various combinations of the above devices, but the disclosure is not limited thereto. The electronic device of the disclosure takes a display device as an example, but the disclosure is not limited thereto. It should be noted that the electronic device may be any combination of the above, but the disclosure is not limited thereto. The following takes a display device in an electronic device as an example to illustrate the disclosure, but the disclosure is not limited thereto.

It should be noted that in the following embodiments, the features in several different embodiments may be replaced, recombined, and mixed to complete other embodiments without departing from the spirit of the disclosure. Features in various embodiments may all be mixed and matched as long as they do not violate the spirit of the disclosure or conflict with each other.

Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions.

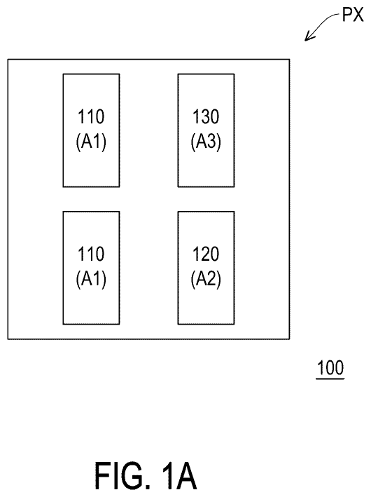

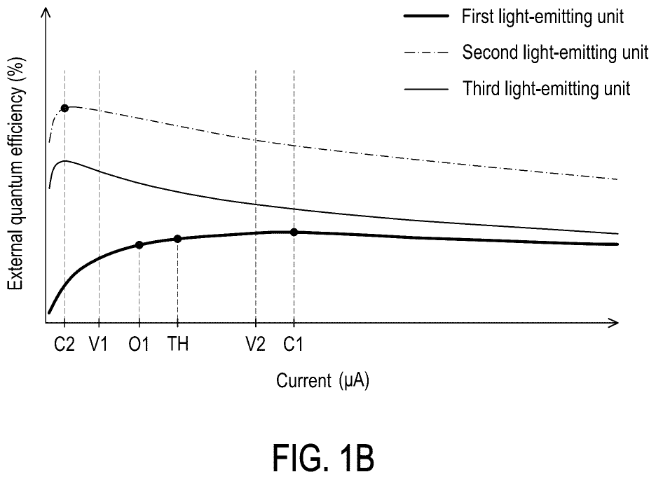

FIG. 1A is a partial top view of the display device of the first embodiment of the disclosure. FIG. 1B is a graph showing the relationship between external quantum efficiency and current of the light-emitting unit in the display device of FIG. 1A.

Referring to FIG. 1A, a display device 100 of the present embodiment may include at least one pixel unit PX, and the at least one pixel unit PX includes at least one first light-emitting unit 110, at least one second light-emitting unit 120, and at least one third light-emitting unit 130. In the following, for convenience of explanation, the first light-emitting unit 110 may be regarded as a red light-emitting diode, the second light-emitting unit 120 may be regarded as a blue light-emitting diode, and the third light-emitting unit 130 may be regarded as a green light-emitting diode, but the disclosure is not limited thereto.

Specifically, the first light-emitting unit 110 has a first light-emitting area A1, and the first light-emitting unit 110 may be operated at a first operating current O1. The second light-emitting unit 120 has a second light-emitting area A2, and the second light-emitting unit 120 is operated at a second operating current O2. The third light-emitting unit 130 has a third light-emitting area A3, and the third light-emitting unit 130 is operated at a third operating current O3. In the present embodiment, the first light-emitting area A1, the second light-emitting area A2, and the third light-emitting area A3 may be substantially the same, but the disclosure is not limited thereto.

In the present embodiment, the outline shapes of the first light-emitting unit 110, the second light-emitting unit 120, and the third light-emitting unit 130 may be substantially the same, but the disclosure is not limited thereto. For example, the outline shapes of the first light-emitting unit 110, the second light-emitting unit 120, and the third light-emitting unit 130 may be rectangular, but the disclosure is not limited thereto. In some embodiments, the outline shapes of the first light-emitting unit, the second light-emitting unit, and the third light-emitting unit may also be square or disk-shaped.

Please refer to FIG. 1B. FIG. 1B shows the external quantum efficiency (EQE) (unit %) of the first light-emitting unit 110, the second light-emitting unit 120, and the third light-emitting unit 130 at different currents in the pixel unit PX. In particular, the first light-emitting unit 110 has the highest external quantum efficiency at a first optimal current C1, the second light-emitting unit 120 has the highest external quantum efficiency at a second optimal current C2, and the first optimal current C1 is greater than the second optimal current C2. For example, the first optimal current C1 is between 80 microamps (μA) and 200 microamps, and the second optimal current C2 is between 1 microamp and 30 microamps. Specifically, the first optimal current C1 may be any value in the range of 80 microamps to 200 microamps (such as 80 microamps, 90 microamps, 100 microamps, 110 microamps, 120 microamps, 130 microamps, 140 microamps, 150 microamps, 160 microamps, 170 microamps, 180 microamps, 190 microamps, 200 microamps, or any value in the range of the above values, but is not limited thereto), and the second optimal current C2 may be any value in the range of 1 microamp to 30 microamps (such as 1 microamp, 5 microamps, 10 microamps, 15 microamps, 20 microamps, 25 microamps, 30 microamps, or any value in the range of the above values, but is not limited thereto), but the disclosure is not limited thereto. In some embodiments, the third light-emitting unit 130 has the highest external quantum efficiency at a third optimal current C3 (not shown), wherein the third optimal current C3 is between 1 microamp and 30 microamps. Specifically, the third optimal current C3 may be any value in the range of 1 microamp to 30 microamps (such as 1 microamp, 5 microamps, 10 microamps, 15 microamps, 20 microamps, 25 microamps, 30 microamps, or any value in the range of the above values, but is not limited thereto). In some embodiments, the third optimal current C3 is less than the second optimal current C2, but the disclosure is not limited thereto.

In the present embodiment, a first current V1 and a second current V2 are respectively defined as any two currents between the first optimal current C1 and the second optimal current C2, and the first current V1 is less than the second current V2. At this time, according to FIG. 1B, it may be seen that the external quantum efficiency of the first light-emitting unit 110 at the first current V1 is less than the external quantum efficiency thereof at the second current V2, and the external quantum efficiency of the second light-emitting unit 120 at the first current V1 is greater than the external quantum efficiency thereof at the second current V2. That is, within the range of the first optimal current C1 and the second optimal current C2, the external quantum efficiency of the first light-emitting unit 110 is increased as the current is increased, but the external quantum efficiency of the second light-emitting unit 120 is decreased as the current is increased. In some embodiments, the external quantum efficiency of the third light-emitting unit 130 at the first current V1 is greater than the external quantum efficiency thereof at the second current V2. Therefore, within the range of the first optimal current C1 and the second optimal current C2, the external quantum efficiency of the third light-emitting unit 130 is decreased as the current is increased.

In the present embodiment, a threshold current TH may be the current between the first optimal current C1 and the second optimal current C2, and the threshold current TH may also be the current between the first current V1 and the second current V2. The threshold current TH may be greater than the first current V1 and less than the second current V2, but the disclosure is not limited thereto. For example, the threshold current TH is between 40 microamps and 80 microamps. Specifically, the threshold current TH may be any value in the range of 40 microamps to 80 microamps (i.e., 40 microamps≤TH≤80 microamps), such as 40 microamps, 50 microamps, 60 microamps, 70 microamps, 80 microamps, or any value in the range of the above values, but the disclosure is not limited thereto. In some embodiments, the difference between the threshold current TH and the second optimal current C2 is less than the difference between the first optimal current C1 and the threshold current TH, but the disclosure is not limited thereto.

For example, the threshold current TH may, for example, be defined as the operating current of the first light-emitting unit 110 corresponding to low power consumption when the pixel unit PX meets the specific target brightness requirements and the color point requirements of the display device, but the disclosure is not limited thereto. In particular, the threshold current TH may be obtained, for example, in the following manner, but is not limited thereto: first, different light-emitting units are removed separately for measurement (or not removed and different grayscale images of different light-emitting units are directly lit up for measurement) to obtain the trend of current and external quantum efficiency of each light-emitting unit (for example, the first light-emitting unit, the second light-emitting unit, and the third light-emitting unit) and obtain the relationship between the current of each light-emitting unit and the corresponding brightness; then, the possible combinations of how many microamps the operating current of each light-emitting unit should need to meet the color point requirements of the display device are calculated, wherein each possible combination may correspond to one brightness value; then, each emission duty ratio corresponding to the brightness value of each possible combination and the target brightness value is calculated; next, the power consumption of each possible combination (for example, the product of the voltage, the sum of the operating currents of each light-emitting unit, and the emission duty ratio) is calculated; then, the combination corresponding to low power consumption is found, so that the current of the light-emitting unit that may emit red light in the combination is used as the threshold current TH. In some embodiments, the threshold current TH is the operating current of the first light-emitting unit 110 corresponding to the minimum power consumption when the pixel unit PX meets the specific target brightness requirements and the color point requirements of the display device.

In the present embodiment, as shown in FIG. 1B, since the first operating current O1 of the first light-emitting unit 110 is less than or equal to the threshold current TH, the external quantum efficiency of the first light-emitting unit 110 at the first operating current O1 is low, so that the first light-emitting unit 110 has the issue of low luminous efficiency or low brightness. For example, the first operating current O1 may be greater than 0 microamps and less than or equal to 60 microamps (i.e., 0 microamps<O1≤60 microamps), but the disclosure is not limited thereto. In some embodiments, the difference between the first operating current O1 and the second optimal current C2 is less than the difference between the first optimal current C1 and the first operating current O1, but the disclosure is not limited thereto. In order to alleviate the issue of low luminous efficiency or low brightness of the first light-emitting unit 110 when the first operating current O1 is less than or equal to the threshold current TH, in the display device 100 of the present embodiment, the luminous efficiency or the brightness of the entire first light-emitting unit 110 in the pixel unit PX is increased by increasing the quantity of the first light-emitting unit 110 in the pixel unit PX, so that each color in the pixel unit PX may meet the requirements of high luminous efficiency or high brightness. That is, in the present embodiment, when the first operating current O1 of the first light-emitting unit 110 is less than or equal to the threshold current TH, the quantity of the first light-emitting unit 110 in the pixel unit PX may be greater than the quantity of the second light-emitting unit 120 and the quantity of the third light-emitting unit 130.

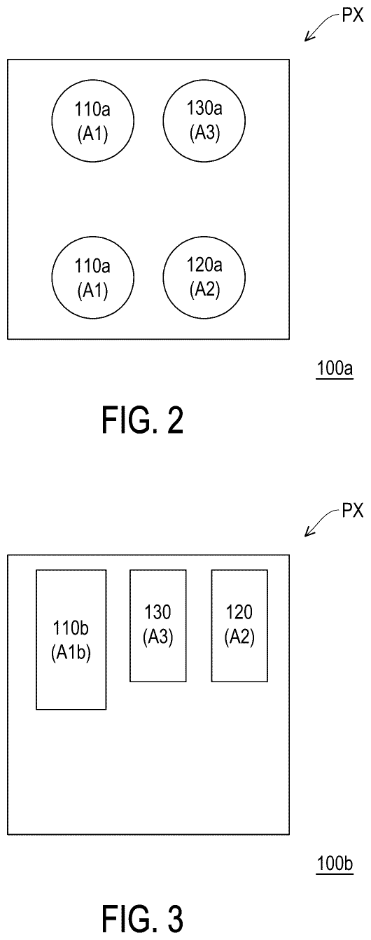

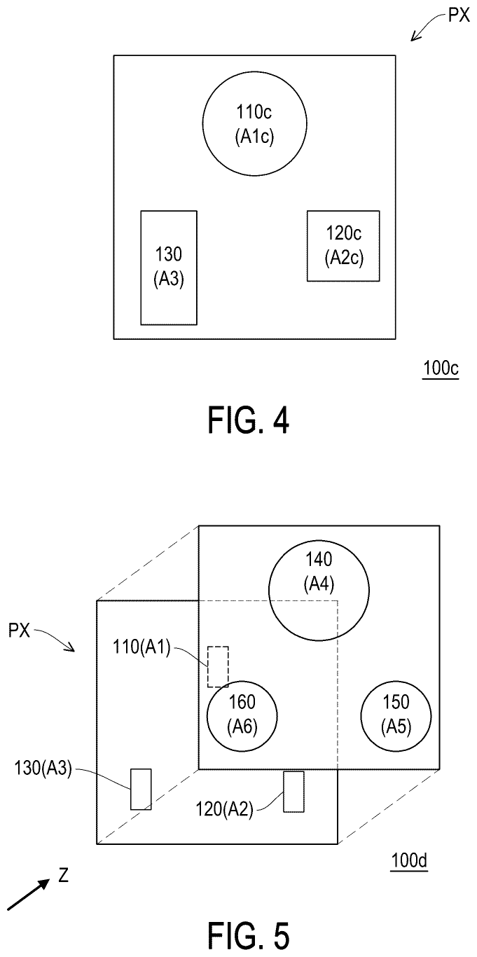

Moreover, in addition to the method of increasing the quantity of the first light-emitting unit 110 in the pixel unit PX, in the display device 100 of the present embodiment, the second operating current O2 of the second light-emitting unit 120 and the third operating current O3 (not shown) of the third light-emitting unit 130 are also correspondingly adjusted, so that the ratio of the first operating current O1 to the second operating current O2 may be 0.8 to 3.5, and the ratio of the third operating current O3 to the second operating current O2 may be 0.8 to 3.2, so that when each color in the pixel unit PX may achieve high luminous efficiency or high brightness requirements, the color point requirements of the display device may also be met at the same time. In the present embodiment, when the first operating current O1 of the first light-emitting unit 110 is less than or equal to the threshold current TH, the ratio of the first operating current O1, the second operating current O2, and the third operating current O3 may be 0.8 to 3.5:1:0.8 to 3.2, but the disclosure is not limited thereto. The description of FIG. 1B and the proportional relationship between the first operating current O1, the second operating current O2, and the third operating current O3 are also applicable to other embodiments in which the operating current O1 of the first light-emitting unit 110 is less than or equal to the threshold current TH, such as the embodiments of FIG. 2, FIG. 3, FIG. 4, and FIG. 5, but the disclosure is not limited thereto.

In the pixel unit PX of the present embodiment, although FIG. 1A schematically shows two first light-emitting units 110, one second light-emitting unit 120, and one third light-emitting unit 130 arranged in an array, the disclosure does not limit the arrangement method and the quantity of the first light-emitting unit 110, the second light-emitting unit 120, and the third light-emitting unit 130 in the pixel unit PX, as long as the quantity of the first light-emitting unit 110 in the pixel unit PX may be greater than the quantity of the second light-emitting unit 120 and the quantity of the third light-emitting unit 130.

Other examples are listed below as illustrations. It should be noted here that the following embodiments adopt the reference numerals and a portion of the content of the above embodiments, wherein the same reference numerals are used to represent the same or similar elements, and the description of the same technical content is omitted. For descriptions of omitted portions, reference may be made to the above embodiments and are not repeated in the following embodiments.

FIG. 2 is a partial top view of the display device of the second embodiment of the disclosure. Please refer to FIG. 2 and FIG. 1A at the same time. A display device 100a of the present embodiment is similar to the display device 100 in FIG. 1A. The difference between the two is: in the display device 100a of the present embodiment, the outline shapes of a first light-emitting unit 110a, a second light-emitting unit 120a, and a third light-emitting unit 130a are disk-shaped.

FIG. 3 is a partial top view of the display device of the third embodiment of the disclosure. Please refer to FIG. 3 and FIG. 1A at the same time. A display device 100b of the present embodiment is similar to the display device 100 in FIG. 1A. The difference between the two is: in the display device 100b of the present embodiment, a first light-emitting area A1b of a first light-emitting unit 110b is different from the second light-emitting area A2 of the second light-emitting unit 120. The first light-emitting area A1b of the first light-emitting unit 110b is different from the third light-emitting area A3 of the third light-emitting unit 130.

Specifically, please refer to FIG. 3. In the present embodiment, the pixel unit PX includes one first light-emitting unit 110b, one second light-emitting unit 120, and one third light-emitting unit 130, and the first light-emitting unit 110b, the second light-emitting unit 120, and the third light-emitting unit 130 are arranged in a straight line along one direction. In the disclosure, the shape and the arrangement method of the light-emitting units are not limited thereto.

In the present embodiment, in order to alleviate the issue of low luminous efficiency or low brightness of the first light-emitting unit 110b when the first operating current O1 is less than or equal to the threshold current TH, in the display device 100b of the present embodiment, the luminous efficiency or the brightness of the first light-emitting units 110b in the pixel unit PX is increased by increasing the first light-emitting area A1b of the first light-emitting unit 110b in the pixel unit PX, so that each color in the pixel unit PX may meet the requirements of high luminous efficiency or high brightness. That is, in the present embodiment, when the first operating current O1 of the first light-emitting unit 110b is less than or equal to the threshold current TH, the first light-emitting area A1b of the first light-emitting unit 110b in the pixel unit PX may be greater than the second light-emitting area A2 of the second light-emitting unit 120. The first light-emitting area A1b of the first light-emitting unit 110b may be greater than the third light-emitting area A3 of the third light-emitting unit 130.

FIG. 4 is a partial top view of the display device of the fourth embodiment of the disclosure. Please refer to FIG. 4 and FIG. 3 at the same time. A display device 100c of the present embodiment is similar to the display device 100b in FIG. 3. The difference between the two is: in the display device 100c of the present embodiment, the outline shape of a first light-emitting unit 110c is disk-shaped, and the outline shape of a second light-emitting unit 120c is square.

Specifically, please refer to FIG. 4. In the present embodiment, the pixel unit PX includes one first light-emitting unit 110c, one second light-emitting unit 120c, and one third light-emitting unit 130, and the first light-emitting unit 110c, the second light-emitting unit 120, and the third light-emitting unit 130c are arranged in a triangle. In the disclosure, the shape and the arrangement method of the light-emitting units are not limited thereto.

In the present embodiment, when the first operating current O1 of the first light-emitting unit 110c is less than or equal to the threshold current TH, a first light-emitting area A1c of the first light-emitting unit 110c in the pixel unit PX may be greater than a second light-emitting area A2c of the second light-emitting unit 120c. The first light-emitting area A1c of the first light-emitting unit 110c may be greater than the third light-emitting area A3 of the third light-emitting unit 130.

FIG. 5 is a partial top view of the display device of the fifth embodiment of the disclosure. Please refer to FIG. 5 and FIG. 1A at the same time. A display device 100d of the present embodiment is similar to the display device 100b in FIG. 3. The difference between the two is: the display device 100d of the present embodiment further includes a first light enhancing unit 140, a second light enhancing unit 150, and a third light enhancing unit 160 disposed on the pixel unit PX.

Specifically, please refer to FIG. 5. In the present embodiment, the pixel unit PX includes one first light-emitting unit 110, one second light-emitting unit 120, and one third light-emitting unit 130, and the first light-emitting unit 110, the second light-emitting unit 120, and the third light-emitting unit 130 are arranged in a triangle.

The first light enhancing unit 140 is disposed on the first light-emitting unit 110, and the first light enhancing unit 140 has a first area A4. The second light enhancing unit 150 is disposed on the second light-emitting unit 120, and the second light enhancing unit 150 has a second area A5. The third light enhancing unit 160 is disposed on the third light-emitting unit 130, and the third light enhancing unit 160 has a third area A6. In the present embodiment, the first light enhancing unit 140, the second light enhancing unit 150, and the third light enhancing unit 160 may be lens structures or other architectures that may be used to increase light intensity, but the disclosure is not limited thereto. In the present embodiment, the outline shapes of the first light enhancing unit 140, the second light enhancing unit 150, and the third light enhancing unit 160 may be disk-shaped, but the disclosure is not limited thereto. In the disclosure, the shape of the light-emitting units, and the shape and the arrangement method of the light enhancing units are not limited thereto.

In the present embodiment, in a normal direction Z of the pixel unit PX, the first light enhancing unit 140 may be overlapped with and correspond to the first light-emitting unit 110, the second light enhancing unit 150 may be overlapped with and correspond to the second light-emitting unit 120, and the third light enhancing unit 160 may be overlapped with and correspond to the third light-emitting unit 130. That is, in the present embodiment, the light enhancing units and the corresponding light-emitting units thereof may have a one-to-one relationship. For example, one first light enhancing unit 140 may correspond to one first light-emitting unit 110, but the disclosure is not limited thereto. In some embodiments not shown, the light enhancing units and the corresponding light-emitting units thereof may also have a one-to-many relationship, for example, one first light enhancing unit corresponds to a plurality of first light-emitting units.

In the present embodiment, the first light-emitting area A1 of the first light-emitting unit 110 in the pixel unit PX may be substantially the same as the second light-emitting area A2 of the second light-emitting unit 120 and the third light-emitting area A3 of the third light-emitting unit 130. However, the first area A4 of the first light enhancing unit 140 may be different from the second area A5 of the second light enhancing unit 150 and the third area A6 of the third light enhancing unit 160.

Specifically, in the present embodiment, in order to alleviate the issue of low luminous efficiency or low brightness of the first light-emitting unit 110 when the first operating current O1 is less than or equal to the threshold current TH, in the display device 100d of the present embodiment, the luminous efficiency or the brightness of the first light-emitting unit 110 in the pixel unit PX is increased by increasing the first area A4 of the first light enhancing unit 140, so that each color in the pixel unit PX may meet the requirements of high luminous efficiency or high brightness. That is, in the present embodiment, when the first operating current O1 of the first light-emitting unit 110 is less than or equal to the threshold current TH, the first area A4 of the first light enhancing unit 140 may be greater than the second area A5 of the second light enhancing unit 150. The first area A4 of the first light enhancing unit 140 may be greater than the third area A6 of the third light enhancing unit 160.

Moreover, without departing from the spirit of the disclosure, the shapes and the arrangement methods of the light-emitting units (or light enhancing units) in FIG. 1A, FIG. 2, FIG. 3, FIG. 4, and FIG. 5 may be replaced, reorganized, mixed and matched to complete other embodiments not shown.

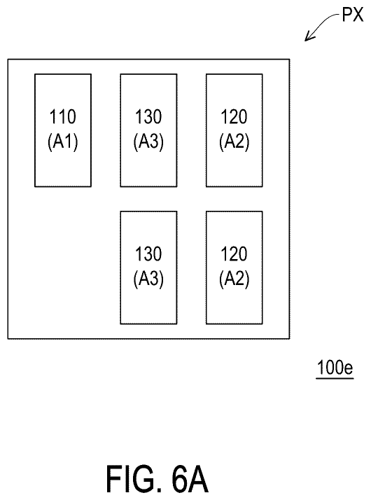

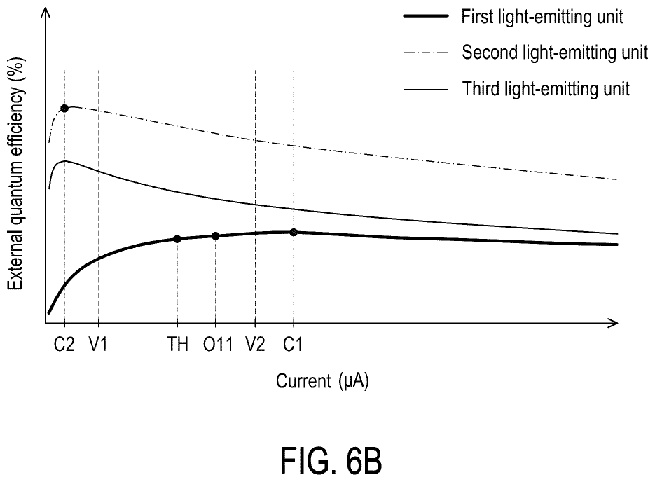

FIG. 6A is a partial top view of the display device of the sixth embodiment of the disclosure. FIG. 6B is a graph showing the relationship between external quantum efficiency and current of the light-emitting unit in the display device of FIG. 6A. Please refer to FIG. 6A to FIG. 6B and FIG. 1A to FIG. 1B at the same time. A display device 100e of the present embodiment is similar to the display device 100 in FIG. 1A, but the difference between the two is: in the display device 100e of the present embodiment, the quantity of the first light-emitting unit 110 in the pixel unit PX is less than the quantity of the second light-emitting unit 120 and the quantity of the third light-emitting unit 130, and the first operating current O11 of the first light-emitting unit 110 is greater than the threshold current TH.

Specifically, please refer to FIG. 6B. Since the first operating current O11 of the first light-emitting unit 110 is greater than the threshold current TH, the external quantum efficiency of the first light-emitting unit 110 at the first operating current O11 is high, so that the first light-emitting unit 110 has high luminous efficiency or high brightness. For example, the first operating current O11 may be greater than 60 microamps and less than or equal to 150 microamps (i.e., 60 microamps<O11≤150 microamps), but the disclosure is not limited thereto. In some embodiments, the difference between the first operating current O11 and the second optimal current C2 is greater than the difference between the first optimal current C1 and the first operating current O11, but the disclosure is not limited thereto. In some embodiments, the difference between the first operating current O11 and the second optimal current C2 is less than or equal to than the difference between the first optimal current C1 and the first operating current O11, but the disclosure is not limited thereto.

Therefore, please refer to FIG. 6A, in order for the pixel unit PX to simultaneously meet the specific target brightness requirements and the color point requirements of the display device and meet the low power consumption target, in the display device 100e of the present embodiment, the quantity of the second light-emitting unit 120 and the quantity of the third light-emitting unit 130 in the pixel unit PX are increased, so that the luminous efficiency or the brightness of the entire second light-emitting unit 120 and the third light-emitting unit 130 in the pixel unit PX may be improved, so that each color in the pixel unit PX may meet the requirements of high luminous efficiency or high brightness. That is, in the present embodiment, when the first operating current O11 of the first light-emitting unit 110 is greater than the threshold current TH, the quantity of the first light-emitting unit 110 in the pixel unit PX may be less than the quantity of the second light-emitting unit 120. In some embodiments, the quantity of first light-emitting unit 110 may be less than the quantity of the third light-emitting unit 130.

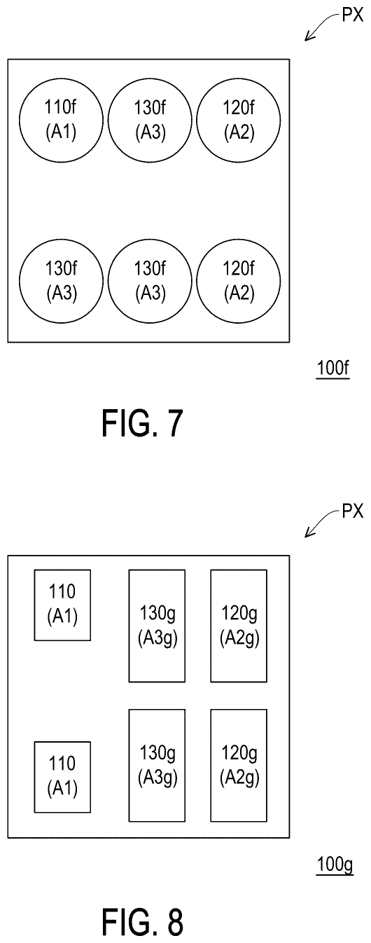

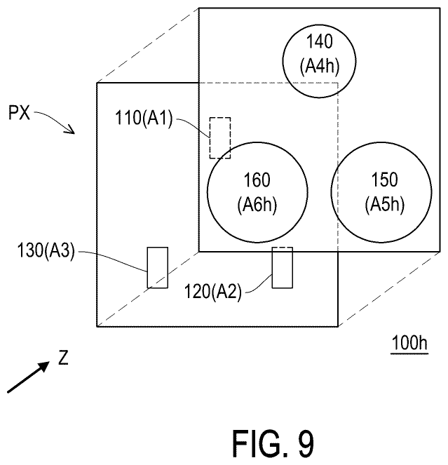

Moreover, in addition to the method of increasing the quantity of the second light-emitting unit 120 and/or the quantity of the third light-emitting unit 130 in the pixel unit PX, in the display device 100e of the present embodiment, a second operating current O21 (not shown) of the second light-emitting unit 120 and a third operating current O31 (not shown) of the third light-emitting unit 130 are also correspondingly adjusted, so that the ratio of the first operating current O11 to the second operating current O21 may be 7 to 12, and the ratio of the third operating current O31 to the second operating current O21 may be 0.5 to 2.5, so that when each color in the pixel unit PX may achieve high luminous efficiency or high brightness requirements, the color point requirements of the display device may also be met at the same time. In other words, in the present embodiment, when the first operating current O11 of the first light-emitting unit 110 is greater than the threshold current TH, the ratio of the first operating current O11, the second operating current O21, and the third operating current O31 may be 7 to 12:1:0.5 to 2.5, but the disclosure is not limited thereto. The description of FIG. 6B and the proportional relationship between the first operating current O1, the second operating current O2, and the third operating current O3 are also applicable to other embodiments in which the operating current O1 of the first light-emitting unit 110 is greater than the threshold current TH, such as the embodiments of FIG. 7, FIG. 8, FIG. 9, and FIG. 10, but the disclosure is not limited thereto.

In the pixel unit PX of the present embodiment, although FIG. 6A schematically shows one first light-emitting unit 110, two second light-emitting units 120, and two third light-emitting units 130 arranged in an array, the disclosure does not limit the arrangement method and the quantity of the first light-emitting unit 110, the second light-emitting unit 120, and the third light-emitting unit 130 in the pixel unit PX, as long as the quantity of the first light-emitting unit 110 in the pixel unit PX may be less than the quantity of the second light-emitting unit 120 and the quantity of the third light-emitting unit 130.

In addition, in the pixel unit PX of the present embodiment, although the quantity of the second light-emitting unit 120 is equal to the quantity of the third light-emitting unit 130, the disclosure is not limited thereto. In some embodiments, the quantity of the second light-emitting unit may also be less than the quantity of the third light-emitting unit, as long as the quantity of the second light-emitting unit in the pixel unit is still greater than the quantity of the first light-emitting unit.

FIG. 7 is a partial top view of the display device of the seventh embodiment of the disclosure. Please refer to FIG. 7 and FIG. 6A at the same time. A display device 100f of the present embodiment is similar to the display device 100e in FIG. 6A. The difference between the two is: in the display device 100f of the present embodiment, the outline shapes of a first light-emitting unit 110f, a second light-emitting unit 120f, and a third light-emitting unit 130f are disk-shaped, and the quantity of the third light-emitting unit 130f may be greater than the quantity of the second light-emitting unit 120f. In the disclosure, the shape and the arrangement method of the light-emitting units are not limited thereto.

FIG. 8 is a partial top view of the display device of the eighth embodiment of the disclosure. Please refer to FIG. 8 and FIG. 6A at the same time. A display device 100g of the present embodiment is similar to the display device 100e in FIG. 6A. The difference between the two is: in the display device 100g of the present embodiment, the first light-emitting area A1 of the first light-emitting unit 110 is different from a second light-emitting area A2g of a second light-emitting unit 120g and a third light-emitting area A3g of a third light-emitting unit 130g, and the quantity of the first light-emitting unit 110 is equal to the quantity of the second light-emitting unit 120g and the quantity of the third light-emitting unit 130g.

Specifically, please refer to FIG. 8. In the present embodiment, the pixel unit PX includes two first light-emitting units 110, two second light-emitting units 120g, and two third light-emitting units 130g.

In the present embodiment, in order for the pixel unit PX to simultaneously meet the specific target brightness requirements and the color point requirements of the display device and meet the low power consumption target, in the display device 100g of the present embodiment, the second light-emitting area A2g of the second light-emitting unit 120g and the third light-emitting area A3g of the third light-emitting unit 130g in the pixel unit PX are increased, so that the luminous efficiency or the brightness of the entire second light-emitting unit 120 and the third light-emitting unit 130 in the pixel unit PX may be improved, so that each color in the pixel unit PX may meet the requirements of high luminous efficiency or high brightness. That is, in the present embodiment, when the first operating current O11 of the first light-emitting unit 110g is greater than the threshold current TH, the first light-emitting area A1 of the first light-emitting unit 110 in the pixel unit PX may be less than the second light-emitting area A2g of the second light-emitting unit 120g and the third light-emitting area A3g of the third light-emitting unit 130g.

FIG. 9 is a partial top view of the display device of the ninth embodiment of the disclosure. Please refer to FIG. 9 and FIG. 6A at the same time. A display device 100h of the present embodiment is similar to the display device 100e in FIG. 6A. The difference between the two is: the display device 100h of the present embodiment also includes the first light enhancing unit 140, the second light enhancing unit 150, and the third light enhancing unit 160 disposed on the pixel unit PX, and the quantity of the first light-emitting unit 110 is equal to the quantity of the second light-emitting unit 120 and the quantity of the third light-emitting unit 130.

Specifically, please refer to FIG. 9. In the present embodiment, the pixel unit PX includes one first light-emitting unit 110, one second light-emitting unit 120, and one third light-emitting unit 130, and the first light-emitting unit 110, the second light-emitting unit 120, and the third light-emitting unit 130 are arranged in a triangle.

The first light enhancing unit 140 is disposed on the first light-emitting unit 110, and the first light enhancing unit 140 has a first area A4H. The second light enhancing unit 150 is disposed on the second light-emitting unit 120, and the second light enhancing unit 150 has a second area A5H. The third light enhancing unit 160 is disposed on the third light-emitting unit 130, and the third light enhancing unit 160 has a third area A6H. In the present embodiment, the first light enhancing unit 140, the second light enhancing unit 150, and the third light enhancing unit 160 may be lens structures or other architectures that may be used to increase light intensity, but the disclosure is not limited thereto. In the present embodiment, the outline shapes of the first light enhancing unit 140, the second light enhancing unit 150, and the third light enhancing unit 160 may be disk-shaped, but the disclosure is not limited thereto. In the disclosure, the shape of the light-emitting unit, and the shape and the arrangement method of the light enhancing unit are not limited thereto.

In the present embodiment, in the normal direction Z of the pixel unit PX, the first light enhancing unit 140 may be overlapped with and correspond to the first light-emitting unit 110, the second light enhancing unit 150 may be overlapped with and correspond to the second light-emitting unit 120, and the third light enhancing unit 160 may be overlapped with and correspond to the third light-emitting unit 130. That is, in the present embodiment, the light enhancing units and the corresponding light-emitting units thereof may have a one-to-one relationship. For example, one first light enhancing unit 140 may correspond to one first light-emitting unit 110, but the disclosure is not limited thereto. In some embodiments not shown, the light enhancing units and the corresponding light-emitting units thereof may also have a one-to-many relationship, for example, one first light enhancing unit corresponds to a plurality of first light-emitting units.

In the present embodiment, the first light-emitting area A1 of the first light-emitting unit 110 in the pixel unit PX may be substantially the same as the second light-emitting area A2 of the second light-emitting unit 120 and the third light-emitting area A3 of the third light-emitting unit 130. However, the first area A4H of the first light enhancing unit 140 may be different from the second area A5H of the second light enhancing unit 150 and the third area A6H of the third light enhancing unit 160.

Specifically, in the present embodiment, in order for the pixel unit PX to simultaneously meet the specific target brightness requirements and the color point requirements of the display device and meet the low power consumption target, in the display device 100h of the present embodiment, the second area A5H of the second light enhancing unit 150 and the third area A6H of the third light enhancing unit 160 are increased, so that the luminous efficiency or the brightness of the entire second light-emitting unit 120 and the third light-emitting unit 130 in the pixel unit PX may be improved, so that each color in the pixel unit PX may meet the requirements of high luminous efficiency or high brightness. That is, in the present embodiment, when the first operating current O1 of the first light-emitting unit 110 is greater than the threshold current TH, the first area A4H of the first light enhancing unit 140 may be less than the second area A5H of the second light enhancing unit 150. The first area A4H of the first light enhancing unit 140 may be less than the third area A6H of the third light enhancing unit 160.

Moreover, without departing from the spirit of the disclosure, the shapes and the arrangement methods of the light-emitting units (or light enhancing units) in FIG. 6A, FIG. 7, FIG. 8, and FIG. 9 may be replaced, reorganized, mixed and matched to complete other embodiments not shown.

Based on the above, in the display device of an embodiment of the disclosure, when the first operating current of the first light-emitting unit is less than or equal to the threshold current, the luminous efficiency or the brightness of the entire first light-emitting unit in the pixel unit may be improved by increasing the quantity of the first light-emitting unit, by increasing the first light-emitting area of the first light-emitting unit, and/or by increasing the first area of the first light enhancing unit; and when the first operating current of the first light-emitting unit is greater than the threshold current, the luminous efficiency or the brightness of the entire second light-emitting unit and the third light-emitting unit in the pixel unit may be improved by increasing the second light-emitting area of the second light-emitting unit and the third light-emitting area of the third light-emitting unit and/or by increasing the second area of the second light enhancing unit and the third area of the third light enhancing unit.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. A display device, comprising:
at least one first light-emitting unit, wherein an external quantum efficiency thereof at a first current is less than an external quantum efficiency thereof at a second current, and the at least one first light-emitting unit is operated at a first operating current; and
at least one second light-emitting unit, wherein an external quantum efficiency thereof at the first current is greater than an external quantum efficiency thereof at the second current, and the at least one second light-emitting unit is operated at a second operating current;
wherein when the first operating current is less than or equal to a threshold current, a quantity of the at least one first light-emitting unit is greater than a quantity of the at least one second light-emitting unit; and when the first operating current is greater than the threshold current, the quantity of the at least one first light-emitting unit is less than the quantity of the at least one second light-emitting unit,
wherein the first current is less than the second current, and the threshold current is greater than the first current and less than the second current.

2. The display device of claim 1, wherein when the first operating current is less than or equal to the threshold current, a ratio of the first operating current to the second operating current is 0.8 to 3.5.

3. The display device of claim 1, wherein when the first operating current is greater than the threshold current, a ratio of the first operating current to the second operating current is 7 to 12.

4. The display device of claim 1, wherein an external quantum efficiency of the at least one first light-emitting unit at a first optimal current is greater than an external quantum efficiency thereof at the second current, an external quantum efficiency of the at least one second light-emitting unit at a second optimal current is greater than an external quantum efficiency thereof at the first current, and the first optimal current is greater than the second optimal current.

5. The display device of claim 4, wherein the first optimal current is between 80 microamps and 200 microamps, and the second optimal current is between 1 microamp and 30 microamps.

6. The display device of claim 4, wherein a difference between the threshold current and the second optimal current is less than a difference between the threshold current and the first optimal current.

7. The display device of claim 4, wherein when the first operating current is less than or equal to the threshold current, a difference between the first operating current and the second optimal current is less than a difference between the first operating current and the first optimal current.

8. The display device of claim 4, wherein when the first operating current is greater than the threshold current, a difference between the first operating current and the second optimal current is greater than a difference between the first operating current and the first optimal current.

9. The display device of claim 1, further comprising:
at least one third light-emitting unit, wherein an external quantum efficiency thereof at the first current is greater than an external quantum efficiency thereof at the second current, and the at least one third light-emitting unit is operated at a third operating current;
wherein when the first operating current is less than or equal to the threshold current, a quantity of the at least one first light-emitting unit is greater than a quantity of the at least one third light-emitting unit; and when the first operating current is greater than the threshold current, the quantity of the at least one first light-emitting unit is less than the quantity of the at least one third light-emitting unit.

10. The display device of claim 9, wherein when the first operating current is less than or equal to the threshold current, a ratio of the third operating current to the second operating current is 0.8 to 3.2.

11. The display device of claim 9, wherein when the first operating current is greater than the threshold current, a ratio of the third operating current to the second operating current is 0.5 to 2.5.

12. The display device of claim 9, wherein an external quantum efficiency of the at least one second light-emitting unit at a second optimal current is greater than an external quantum efficiency thereof at the first current, an external quantum efficiency of the at least one third light-emitting unit at a third optimal current is greater than an external quantum efficiency thereof at the first current, and the second optimal current is greater than the third optimal current.

13. The display device of claim 12, wherein the second optimal current is between 1 microamp and 30 microamps, and the third optimal current is between 1 microamp and 30 microamps.

14. The display device of claim 9, wherein the at least one first light-emitting unit is a red light-emitting diode, the at least one second light-emitting unit is a blue light-emitting diode, and the at least one third light-emitting unit is a green light-emitting diode.

15. The display device of claim 9, wherein outline shapes of the at least one first light-emitting unit, the at least one second light-emitting unit, and the at least one third light-emitting unit are rectangular, square, or disk-shaped.

16. A display device, comprising:
at least one first light-emitting unit having a first light-emitting area, wherein an external quantum efficiency thereof at a first current is less than an external quantum efficiency thereof at a second current, and the at least one first light-emitting unit is operated at a first operating current; and
at least one second light-emitting unit having a second light-emitting area, wherein an external quantum efficiency thereof at the first current is greater than an external quantum efficiency thereof at the second current;
wherein when the first operating current is less than or equal to a threshold current, the first light-emitting area is greater than the second light-emitting area; and when the first operating current is greater than the threshold current, the first light-emitting area is less than the second light-emitting area,
wherein the first current is less than the second current, and the threshold current is greater than the first current and less than the second current.

17. The display device of claim 16, further comprising:
at least one third light-emitting unit having a third light-emitting area, wherein an external quantum efficiency thereof at the first current is greater than an external quantum efficiency thereof at the second current;
wherein when the first operating current is less than or equal to the threshold current, the first light-emitting area is greater than the third light-emitting area; and when the first operating current is greater than the threshold current, the first light-emitting area is less than the third light-emitting area.

18. The display device of claim 17, wherein outline shapes of the at least one first light-emitting unit, the at least one second light-emitting unit, and the at least one third light-emitting unit are rectangular, square, or disk-shaped.

19. A display device, comprising:
at least one first light-emitting unit, wherein an external quantum efficiency thereof at a first current is less than an external quantum efficiency thereof at a second current, and the at least one first light-emitting unit is operated at a first operating current;
a first light enhancing unit disposed on the at least one first light-emitting unit and having a first area;
at least one second light-emitting unit, wherein an external quantum efficiency thereof at the first current is greater than an external quantum efficiency thereof at the second current; and
a second light enhancing unit disposed on the at least one second light-emitting unit and having a second area;
wherein when the first operating current is less than or equal to a threshold current, the first area is greater than the second area; and when the first operating current is greater than the threshold current, the first area is less than the second area,
wherein the first current is less than the second current, and the threshold current is greater than the first current and less than the second current.

20. The display device of claim 19, further comprising:
at least one third light-emitting unit, wherein an external quantum efficiency thereof at the first current is greater than an external quantum efficiency thereof at the second current; and
a third light enhancing unit disposed on the at least one third light-emitting unit and having a third area;
wherein when the first operating current is less than or equal to the threshold current, the first area is greater than the third area; and when the first operating current is greater than the threshold current, the first area is less than the third area.
